(19) United States
(12) Patent Application Publication
(10) Pub. No.: US 2011/0226505 A1
(43) Pub. Date: Sep. 22, 2011

(54) WALK-IN OUTDOOR ELECTRONIC EQUIPMENT ENCLOSURE

(75) Inventor: Christian Campbell Mackin, Aliso Viejo, CA (US)

(73) Assignee: POWERWAVE TECHNOLOGIES, INC., Santa Ana, CA (US)

(21) Appl. No.: 13/047,590

(22) Filed: Mar. 14, 2011

Related U.S. Application Data
(60) Provisional application No. 61/314,525, filed on Mar. 16, 2010.

(51) Int. Cl. H05K 5/06; H05K 5/00; H05K 7/20

(52) U.S. Cl. 174/50.5; 174/520; 174/547

(57) ABSTRACT

An enclosure that provides a temporary sheltered service access area is disclosed. The outdoor electronics enclosure comprises a fixed cabinet which holds electronic equipment and a housing that is attached to the fixed cabinet with slide rails. The housing has a top panel, a service access door, two vertical panels, and a raised floor. The housing is movable from a closed position in which the housing is immediately adjacent to and partially surrounds the fixed cabinet to an open position in which the housing is moved away from the fixed cabinet in a horizontal direction to define an internal service access area within the housing for servicing the electronic equipment. Service technicians enter the sheltered service area and maintain electronic equipment in the fixed cabinet.

### RELATED APPLICATION INFORMATION

The present application claims priority under 35 U.S.C. Section 119(e) to U.S. Provisional Patent Application Ser. No. 61/314,525 filed Mar. 16, 2010, the disclosure of which is incorporated herein by reference in its entirety.

### BACKGROUND OF THE INVENTION

1. Field of the Invention

The present invention relates generally to outdoor enclosures for holding and sheltering electronic equipment. More particularly, the invention relates to outdoor enclosures having electronic equipment requiring access for maintenance of the equipment.

2. Description of the Prior Art and Related Background Information

Modern telecommunication systems utilize outdoor cabinets to house electronic equipment. Servicing the equipment typically requires technicians to open doors on the outdoor cabinets to gain access to the electronic equipment. However, this approach exposes the technicians and the electronic equipment to the outdoor environment which may damage the electronic equipment in inclement weather.

Accordingly, a need exists to protect electronic equipment and service technicians during maintenance.

### SUMMARY OF THE INVENTION

In the first aspect, the present invention provides an outdoor electronics enclosure comprising a fixed cabinet configured for holding electronic equipment, and a housing slideably coupled to the fixed cabinet, wherein the housing is movable from a closed position in which the housing is immediately adjacent to and partially surrounds the fixed cabinet to an open position in which the housing is moved away from the fixed cabinet in a horizontal direction to define an internal service access area within the housing for servicing the electronic equipment.

In a preferred embodiment of the outdoor electronics enclosure, the housing forms a weather-tight seal around the fixed cabinet in the closed position. The housing preferably has a service access door, where the housing forms a weather-tight seal around the internal service access area when the housing is in the open position and the service access door is closed. The housing preferably has two vertical panels, a floor; and, an open frame having a plurality of stiles and rails configured for coupling to the two vertical panels, the service access door, and the floor. One of the two vertical panels preferably comprises a second service access door. The outdoor electronics enclosure preferably has at least one sliding rail configured for slideably coupling the housing to the fixed cabinet. The outdoor electronics enclosure preferably has a heat exchanger system coupled to one of the two vertical panels of the housing. The heat exchanger system is preferably configured for cooling the electronic equipment in both the open and closed positions. The fixed cabinet preferably holds an Electronic Industries Association (“EIA”) equipment rack.

In another aspect, the present invention provides an outdoor electronics enclosure comprising a fixed cabinet configured for holding electronic equipment, a housing having a top panel, two vertical panels, a service access door, and a floor. The outdoor electronics enclosure has at least one slide rail wherein one end of the slide rail is coupled to the housing and the opposite end of the slide rail is coupled to the fixed chamber, wherein the housing is movable from a closed position in which the housing is immediately adjacent to and partially surrounds the fixed cabinet to an open position in which the housing is moved away from the fixed cabinet in a horizontal direction to define an internal service access area within the housing for servicing the electronic equipment.

In a preferred embodiment of the present invention, the housing forms a weather-tight seal around the fixed cabinet in the closed position. The outdoor electronics enclosure preferably has a plinth coupled to the bottom of the fixed cabinet, where the housing forms a weather-tight seal around the internal service access area when the housing is in the open position and the service access door is closed. The housing preferably has an open frame having a plurality of stiles and rails configured for coupling to the two vertical panels, the service access door, and the floor. One of the two vertical panels preferably comprises a second service access door. The outdoor electronics enclosure preferably further comprising a heat exchanger system coupled to one of the two vertical panels of the housing. The heat exchanger system is preferably configured for cooling the electronic equipment in both the open and closed positions. The fixed cabinet preferably holds an Electronic Industries Association (“EIA”) equipment rack.

In another aspect, the present invention provides an outdoor electronics shelter system, the system having a plurality of outdoor electronics enclosures. Each outdoor electronics enclosure has a fixed cabinet configured for holding electronic equipment, a housing having a top panel, two vertical panels, a service access door, and a floor. Each outdoor electronics enclosure has at least one slide rail wherein one end of the slide rail is coupled to the housing and the opposite end of the slide rail is coupled to the fixed chamber, wherein the housing is movable from a closed position in which the housing is immediately adjacent to and partially surrounds the fixed cabinet to an open position in which the housing is moved away from the fixed cabinet in a horizontal direction to define an internal service access area within the housing for servicing the electronic equipment. Each outdoor electronics enclosure is located immediately adjacent to a neighboring outdoor electronics enclosure.

In a preferred embodiment of the present invention, the housing of each outdoor enclosure forms a weather-tight seal around the corresponding fixed cabinet in the closed position. The outdoor electronics enclosure preferably further comprising a plinth coupled to the bottom of the fixed cabinet, where the housing of each outdoor enclosure forms a weather-tight seal around the corresponding internal service access area when the housing is in the open position.

Further features and aspects of the invention are set out in the following detailed description.

### BRIEF DESCRIPTION OF THE DRAWINGS

FIG. 1A is a perspective view of an outdoor electronics enclosure in an open position in accordance with an embodiment of the present invention.

FIG. 1B is a perspective view of an outdoor electronics enclosure in a closed position in accordance with an embodiment of the present invention.

FIGS. 2A and 2B are front and side views respectively of an outdoor electronics enclosure in accordance with an embodiment of the present invention.

FIG. 3 is a perspective view of an outdoor electronics enclosure illustrating a service access area formed within the housing in accordance with an embodiment of the present invention.

FIGS. 4A, 4B, and 4C are front, side, and top views respectively of an outdoor electronics enclosure with the service access doors opened in accordance with an embodiment of the present invention.

FIG. 5 is a front view of the fixed cabinet in accordance with an embodiment of the present invention.

FIG. 6 is an exploded, perspective view of an outdoor electronics enclosure in accordance with an embodiment of the present invention.

FIG. 7 is a perspective view of two outdoor electronics enclosures.

### DETAILED DESCRIPTION OF THE INVENTION

It is an object of the present invention to provide a temporary, sheltered service access area for an outdoor electronics enclosure. The outdoor electronics enclosure comprises a fixed cabinet which holds electronic equipment and a housing that is attached to the fixed cabinet with slide rails. The housing has a top panel, a service access door, two vertical panels, and a raised floor. The housing is movable from a closed position to an open position. When the housing is in a closed position, the housing is placed immediately adjacent to and partially surrounds the fixed cabinet. When the housing is placed in an open position, the housing is moved away from the fixed cabinet in a horizontal direction to define an internal service access area within the housing for servicing the electronic equipment. During standard operation, the housing is placed in the closed position. When the electronic equipment is to be maintained, a service technician pulls the housing to the open position to form an internal service access area within the housing. The technician opens the service access door, steps up and enters the service access area, and then closes the service access door. The technician then services the electronics equipment sheltered from the outdoor environment. The housing preferably has a heat exchanger such that the electronic equipment remains in a cooled environment during the servicing. The outdoor electronics enclosure is compact and lightweight and accommodates small lease spaces while providing unprecedented levels of flexibility to support a wide array of deployment scenarios. The outdoor electronics enclosure protects the electronic equipment from the elements while providing the requisite ease of access for maintenance.

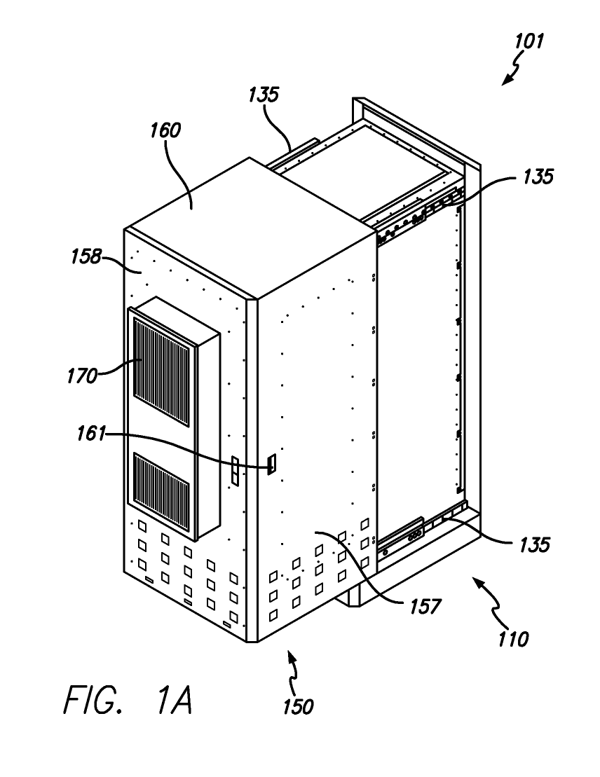

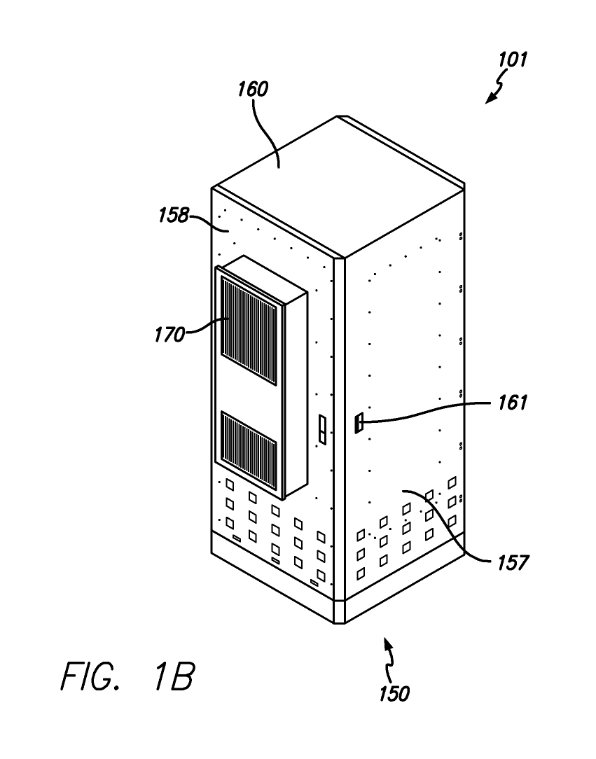

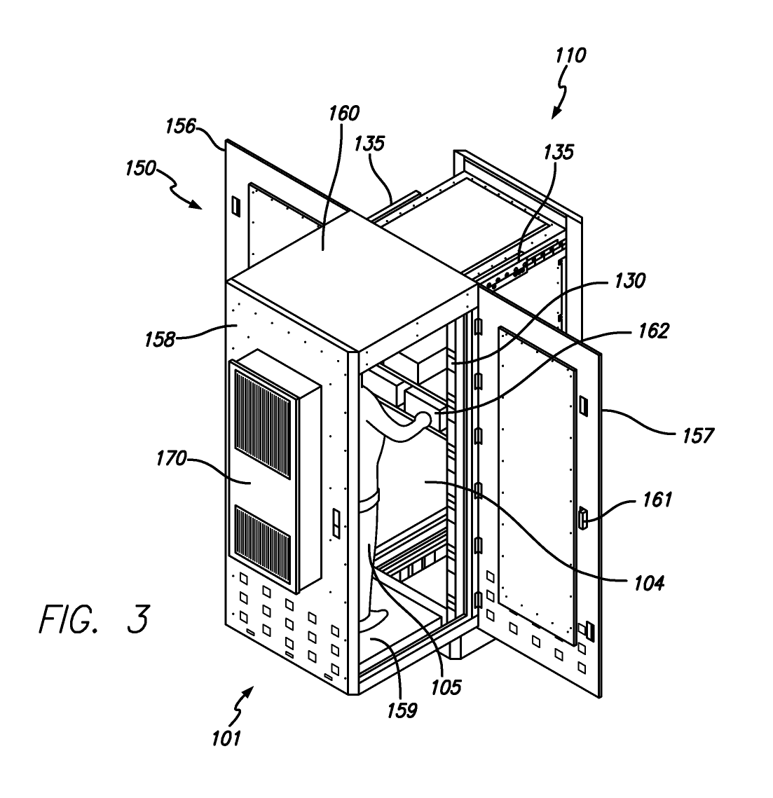

FIG. 1A is a perspective view of an outdoor electronics enclosure 101 in a preferred embodiment of the invention. The outdoor electronics enclosure 101 may be in a preferred application a multi-purpose cell site enclosure that provides network operators and technicians with a flexible, secure and compact housing solution for wireless infrastructure and other equipment with requisite accessibility for ease of maintenance. The outdoor electronics enclosure comprises a fixed cabinet 110 for holding electronic equipment and a housing 150. The housing 150 has a top panel 160, a right service access door 157, a heat exchanger 170 mounted on a front panel 158, and a left service access door 156 and a floor 159 as depicted in FIG. 3. The housing 150 is slideably coupled to the fixed cabinet such that the housing 150 can move from a closed position, as depicted in FIG. 1B to an open position as depicted in FIG. 1A. In the closed position, the housing 150 is immediately adjacent to and partially surrounds the fixed cabinet 110 as depicted in FIG. 1B. In the open position, the housing 150 is moved away from the fixed cabinet 110 in a horizontal direction as depicted in FIG. 1A to define an internal service access area 104 within the housing for servicing the electronic equipment as depicted in FIG. 3. Slide rails 135 preferably couple the housing 150 to the fixed cabinet 110.

The housing 150 preferably forms a weather-tight seal around the fixed cabinet 110 in the closed and open positions to ensure critical equipment is protected even in the most extreme environments, such as in wind-driven rain, and salt fog in coastal deployments. Advanced materials around all doors 156, 157, 158 and top panel 160 provide superior water-tight protection. While in the open position, the housing 160 preferably partially extends over and beyond the fixed cabinet 110 to prevent the outdoor elements from entering the service access area 104.

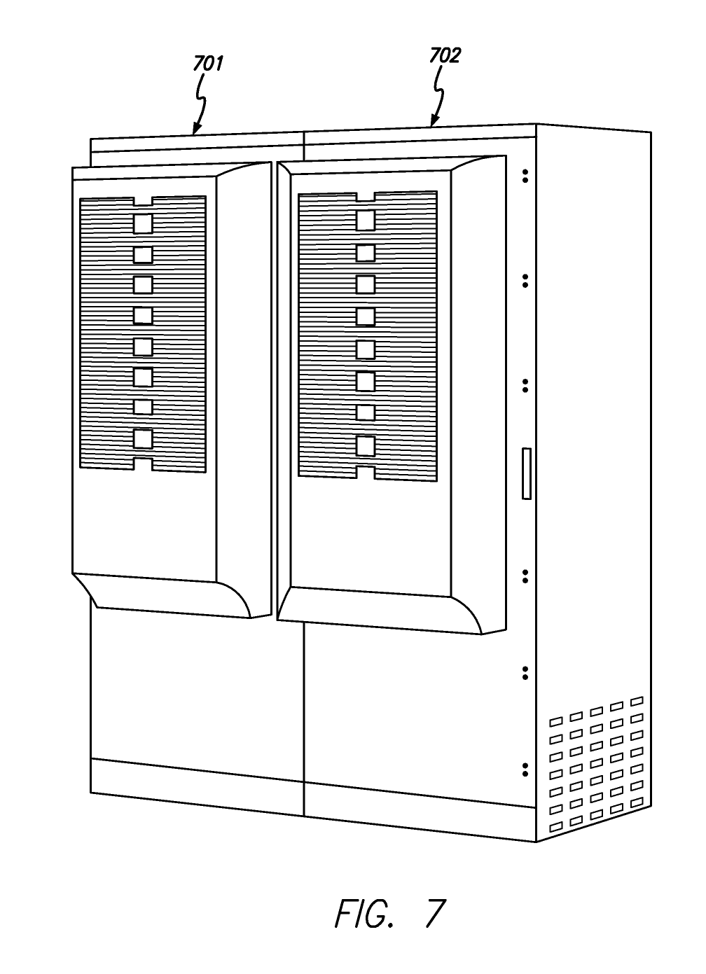

The outdoor electronics enclosure 101 can also function as a key component to assist wireless operators in complying with the Federal Communications Commission's mandate for eight hours of backup power. All power options ensure hydrogen safety with passive ventilation via a semi-permeable Teflon membrane. The outdoor electronics enclosure 101 exhibits high energy efficiency because of the thermal management system featuring a closed loop air-to-air heat exchanger system 170 which lowers overall operating expenses. The outdoor electronics enclosure 101 has a modular design which supports the ability to add additional cabinets as future growth requirements dictate, such as shown in FIG. 7 discussed below.

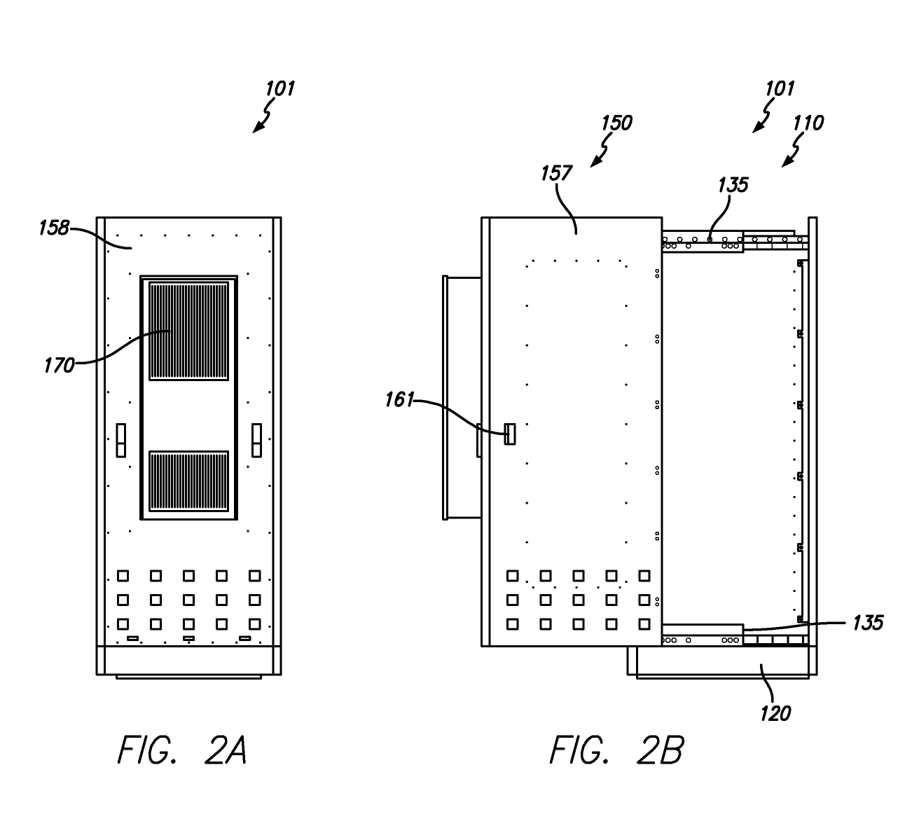

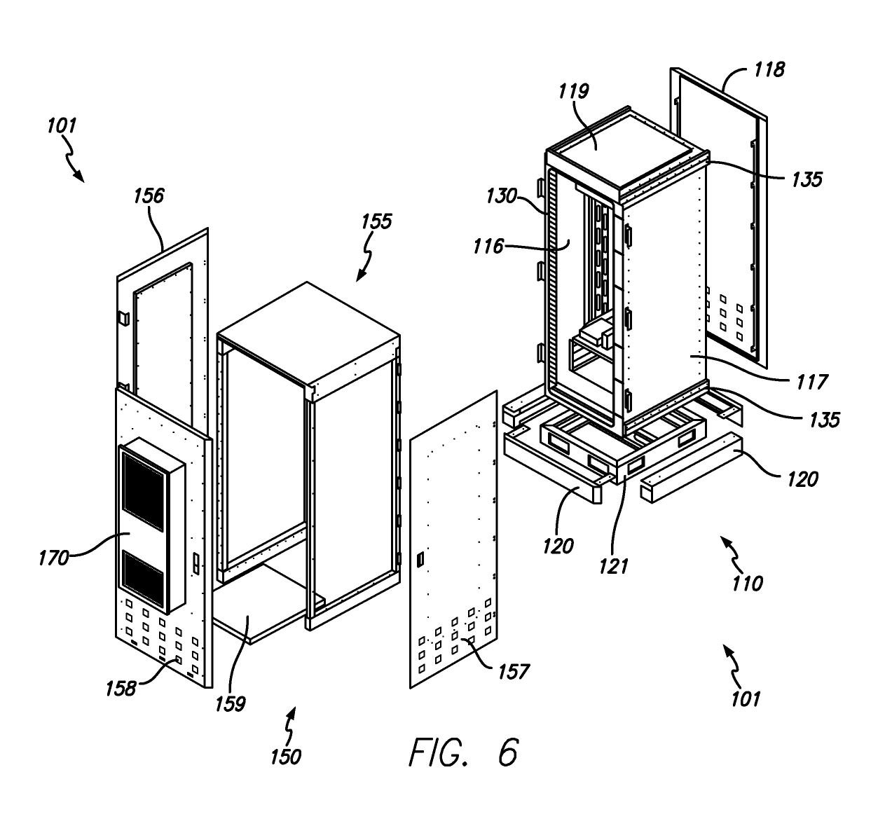

FIGS. 2A and 2B are front and side views respectively of the outdoor electronics enclosure 101. The bottom of fixed cabinet 110 is attached to a plinth 121, illustrated in FIG. 6, which is surrounded by plinth covers 120. FIG. 3 is a perspective view of an outdoor electronics enclosure 101 illustrating a service access area 104 formed within the housing 150 in accordance with an embodiment of the present invention. Once the housing 150 is slid away from the fixed cabinet 110, a service technician 105 opens door 156 or 157 with the door handle 161 to reveal a service access area 104. The technician 105 steps up to the floor 159 and enters the service access area 104 to perform maintenance on the electronic equipment 162 housed within the fixed cabinet 110. The service technician 105 shuts the doors 156 and 157 and is environmentally insulated by doors 156 and 157, top panel 160, floor 159 and the fixed cabinet 110. The heat exchanger 170 preferably continuously cools the electronic equipment 162 in the fixed cabinet 110 during the service maintenance.

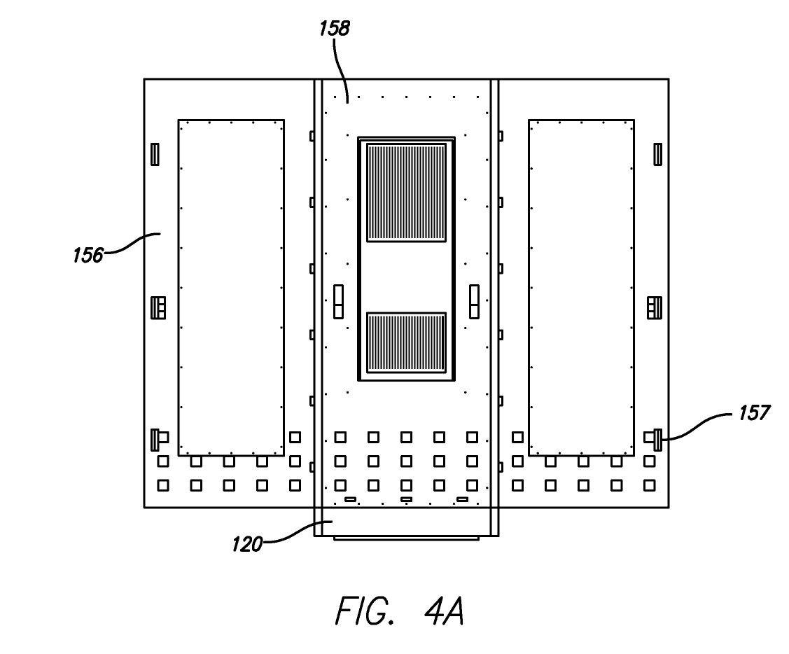

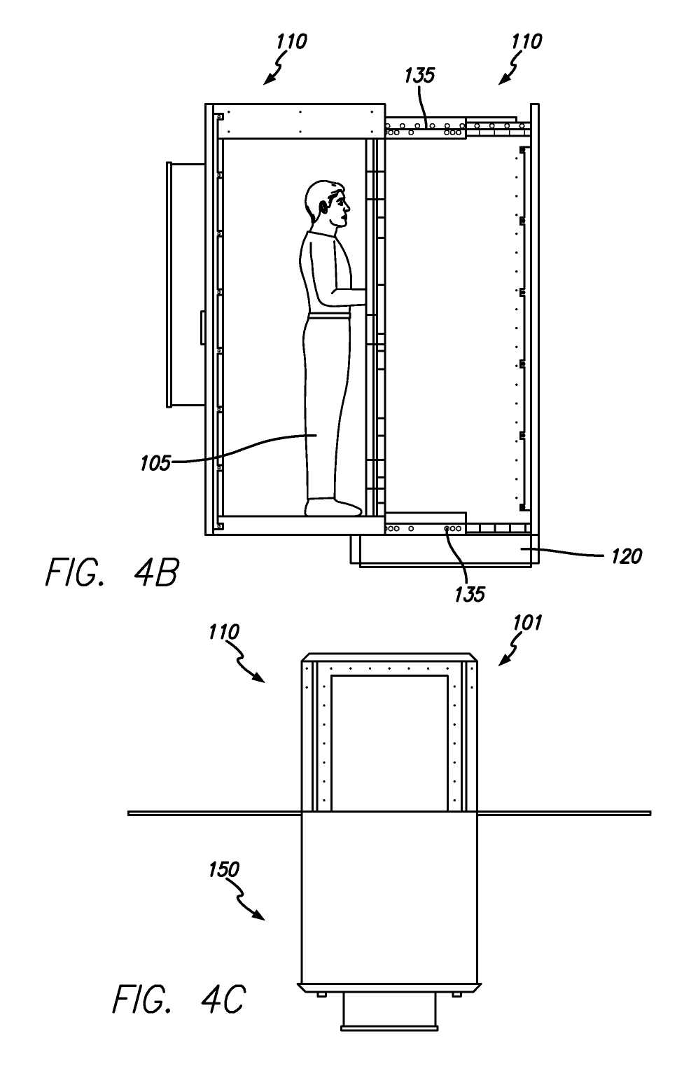

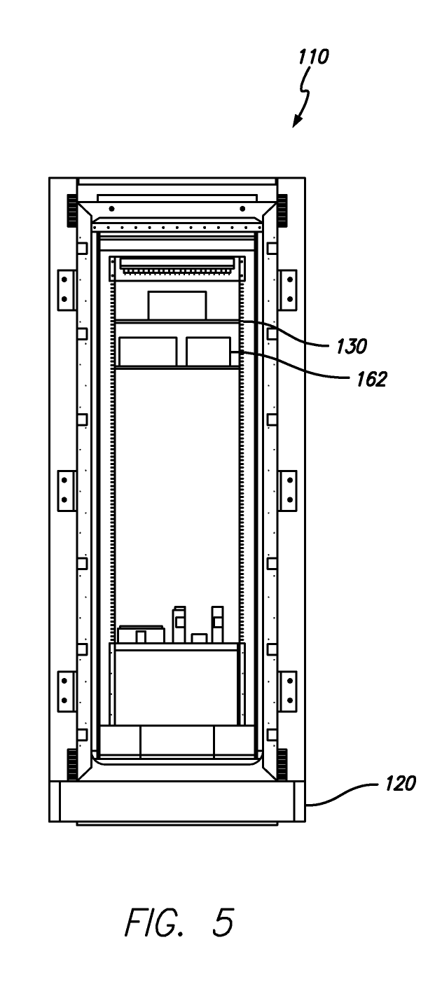

FIGS. 4A, 4B, and 4C are front, side, and top views respectively of an outdoor electronics enclosure with the access doors opened in accordance with an embodiment of the present invention. FIG. 5 is a front view of the fixed cabinet in accordance with an embodiment of the present invention. The fixed cabinet 110 has an electronics rack 130 configured for holding electronic equipment 162. For example, the fixed cabinet 110 offers a flexible configuration which supports a wide range of wireless infrastructure components, power supplies, batteries, radios, and any Electronic Industries Association (EIA) 19-inch or 23-inch standard form factor equipment. This further extends the flexibility of the outdoor electronics enclosure 101 to enable operators to diversify operations by housing lightweight mobile data center equipment.

FIG. 6 is an exploded, perspective view of an outdoor electronics enclosure 101 in accordance with an embodiment of the present invention. The fixed cabinet 110 has a left panel 116, a right panel 117, a back panel 118, and a top panel 119 which surround the rack 130. Fixed cabinet 110 is placed on top of plinth 121 which are surrounded by plinth covers 120. The housing 150 has a housing frame 155 having a plurality of stiles and rails configured for coupling to the left service access door 156, the right service access door 157, the front panel 158, and the floor 159. The housing frame 155 preferably is a welded aluminum uni-frame that is both aesthetically pleasing and weather-tight to ensure critical equipment is protected even in the most extreme environments, such as in wind-driven rain, and salt fog in coastal deployments. Advanced materials around all doors 156 and 157 and top surface of housing frame 155 provide superior water-tight protection.

FIG. 7 is a perspective view of outdoor electronics enclosure 701 located immediately adjacent to a second electronics enclosure 702. Offering small footprint and rigorous protection, the outdoor electronics enclosures 701 and 702 have small footprints and are ideal for site deployments requiring one-to-two enclosures which can be further expanded to include four or more outdoor enclosures.

The present invention has been described primarily to provide a temporary, sheltered service access area for an outdoor electronics enclosure employing a pull out housing attached to a fixed cabinet. In this regard, the enclosures for providing the temporary sheltered service area are presented for purposes of illustration and description. Furthermore, the description is not intended to limit the invention to the form disclosed herein. Accordingly, variants and modifications consistent with the following teachings, skill, and knowledge of the relevant art, are within the scope of the present invention. The embodiments described herein are further intended to explain modes known for practicing the invention disclosed herewith and to enable others skilled in the art to utilize the invention in equivalent, or alternative embodiments and with various modifications considered necessary by the particular application(s) or use(s) of the present invention.

What is claimed is:

1. An outdoor electronics enclosure comprising:
a fixed cabinet configured for holding electronic equipment; and
a housing slideably coupled to the fixed cabinet, wherein the housing is movable from a closed position in which the housing is immediately adjacent to and partially surrounds the fixed cabinet to an open position in which the housing is moved away from the fixed cabinet in a horizontal direction to define an internal service access area within the housing for servicing the electronic equipment.

2. The outdoor electronics enclosure of claim 1, wherein the housing forms a weather-tight seal around the fixed cabinet in the closed position.

3. The outdoor electronics enclosure of claim 2, wherein the housing further comprising a service access door, wherein the housing forms a weather-tight seal around the internal service access area when the housing is in the open position and the service access door is closed.

4. The outdoor electronics enclosure of claim 3, wherein the housing further comprises:
two vertical panels;
a floor; and,
an open frame having a plurality of stiles and rails configured for coupling to the two vertical panels, the service access door, and the floor.

5. The outdoor electronics enclosure of claim 4, wherein one of the two vertical panels comprises a second service access door.

6. The outdoor electronics enclosure of claim 1, further comprising at least one sliding rail configured for slideably coupling the housing to the fixed cabinet.

7. The outdoor electronics enclosure of claim 1, further comprising a heat exchanger system coupled to one of the two vertical panels of the housing.

8. The outdoor electronics enclosure of claim 7, wherein the heat exchanger system is configured for cooling the electronic equipment in both the open and closed positions.

9. The outdoor electronics enclosure of claim 1, wherein the fixed cabinet holds an Electronic Industries Association (“EIA”) equipment rack.

10. An outdoor electronics enclosure comprising:
a fixed cabinet configured for holding electronic equipment;
a housing having a top panel, two vertical panels, a service access door, and a floor; and,
at least one slide rail wherein one end of the slide rail is coupled to the housing and the opposite end of the slide rail is coupled to the fixed chamber, wherein the housing is movable from a closed position in which the housing is immediately adjacent to and partially surrounds the fixed cabinet to an open position in which the housing is moved away from the fixed cabinet in a horizontal direction to define an internal service access area within the housing for servicing the electronic equipment.

11. The outdoor electronics enclosure of claim 10, wherein the housing forms a weather-tight seal around the fixed cabinet in the closed position.

12. The outdoor electronics enclosure of claim 11, further comprising a plinth coupled to the bottom of the fixed cabinet, wherein the housing forms a weather-tight seal around the internal service access area when the housing is in the open position and the service access door is closed.

13. The outdoor electronics enclosure of claim 10, wherein the housing further comprises an open frame having a plurality of stiles and rails configured for coupling to the two vertical panels, the service access door, and the floor.

14. The outdoor electronics enclosure of claim 13, wherein one of the two vertical panels comprises a second service access door.

15. The outdoor electronics enclosure of claim 10, further comprising a heat exchanger system coupled to one of the two vertical panels of the housing.

16. The outdoor electronics enclosure of claim 15, wherein the heat exchanger system is configured for cooling the electronic equipment in both the open and closed positions.

17. The outdoor electronics enclosure of claim 10, wherein the fixed cabinet holds an Electronic Industries Association (“EIA”) equipment rack.

18. An outdoor electronics shelter system, the system comprising:
a plurality of outdoor electronics enclosures, each outdoor electronics enclosure comprising:
a fixed cabinet configured for holding electronic equipment;
a housing having a top panel, two vertical panels, a service access door, and a floor;
at least one slide rail wherein one end of the slide rail is coupled to the housing and the opposite end of the slide rail is coupled to the fixed chamber, wherein the housing is movable from a closed position in which the housing is immediately adjacent to and partially surrounds the fixed cabinet to an open position in which the housing is moved away from the fixed cabinet in a horizontal direction to define an internal service access area within the housing for servicing the electronic equipment.
wherein each outdoor electronics enclosure is located immediately adjacent to a neighboring outdoor electronics enclosure.

19. The outdoor electronics shelter system of claim 18, wherein the housing of each outdoor enclosure forms a weather-tight seal around the corresponding fixed cabinet in the closed position.

20. The outdoor electronics enclosure of claim 19, further comprising a plinth coupled to the bottom of the fixed cabinet, wherein the housing of each outdoor enclosure forms a weather-tight seal around the corresponding internal service access area when the housing is in the open position.
